(19) United States
(12) Patent Application Publication
(10) Pub. No.: US 2012/0329182 A1
(43) Pub. Date: Dec. 27, 2012

(54) SEMICONDUCTOR DEVICE MOUNTING METHOD

(76) Inventors: Teppei Kojio, Osaka (JP); Masashi Matsumori, Osaka (JP); Tadahiko Sakai, Osaka (JP); Takatoshi Ishikawa, Yamanashi (JP)

(21) Appl. No.: 13/512,955

(22) PCT Filed: Oct. 26, 2011
(86) PCT No.: PCT/JP2011/005978

§ 371 Date: May 31, 2012

(30) Foreign Application Priority Data
Mar. 28, 2011 (JP) 2011-070310
Mar. 28, 2011 (JP) 2011-070318

(51) Int. Cl. H01L 21/607; H01L 33/52; H01L 33/62; H01L 21/56

(52) U.S. Cl. 438/26; 438/121; 438/124; 257/E33.059; 257/E33.066; 257/E21.518; 257/E21.502

(57) ABSTRACT

When metal junction between a first electrode and a second electrode is executed as ultrasonic bonding between metals including at least copper, the ultrasonic bonding is performed in a state that a contact interface between the first electrode and the second electrode is covered with a bonding auxiliary agent. As a result, formation of oxide at a bonding interface between the first electrode and the second electrode due to execution of the ultrasonic bonding can be suppressed. Therefore, while a desired bonding strength is ensured, ultrasonic bonding with copper used for the first electrode or the second electrode can be fulfilled and cost cuts in mounting of semiconductor devices can be achieved.

### TECHNICAL FIELD

The present invention relates to a method for mounting a semiconductor device by ultrasonic bonding of second electrodes of the semiconductor device to first electrodes in a circuit board.

### BACKGROUND ART

Conventionally, there have been known various types of such semiconductor device mounting methods using ultrasonic bonding as shown above. In such a conventional semiconductor device mounting method, while Au bumps (second electrodes) formed in a semiconductor device are kept pressed against Au electrodes (first electrodes) formed in connection with interconnecting lines of the board, ultrasonic vibrations are applied to a contact interface so that the Au bumps and the Au electrodes are bonded together by metal junction (i.e., Au—Au junction). Thus, semiconductor devices are mounted on the board by such a procedure described above (see, e.g., PTL 1 or 2).

### PATENT LITERATURE

PTL1: JP 2000-68327 A
PTL2: JP 2001-237270 A

### SUMMARY OF INVENTION

### Technical Problem

In recent years, there has been an increasing demand for cost cuts in various types of electronic equipment in which device-mounted boards manufactured with such semiconductor devices mounted thereon as described above are contained. For this purpose, various contrivances for cost cuts in semiconductor device mounting are desired.

From a viewpoint of material costs, a cost for Au electrodes used in the board is high, and replacing the Au electrodes with lower-priced Cu electrodes, if allowed, makes it possible to realize cost cuts. For example, in a mode in which Au bumps of a light-emitting device (LED chip) as a semiconductor device are ultrasonically bonded to Au electrodes of the board, if the Au electrodes of the board can be replaced with Cu electrodes while reliability of the Au—Cu metal junction is kept equivalent to that of the Au—Au metal junction, it becomes practicable to achieve large extents of cost cuts while the bonding reliability is maintained.

Inventors of the present invention, after performing a process for removal of oxide formed on surfaces of Cu electrodes of the board, performed ultrasonic bonding of the Cu electrodes of the oxide-removed board and the Au bumps of the semiconductor device to each other in the atmospheric air, by which after-junction shearing strength was measured. However, although the oxide of the Cu electrodes had been removed beforehand, not enough shearing strength was obtained.

An object of the invention, lying in solving the above-described problems, is to provide a semiconductor device mounting method for performing ultrasonic bonding of a second electrode of a semiconductor device to a first electrode of a board, the method capable of fulfilling metal junction between the first electrode and the second electrode as a junction between metals including at least copper while a required bonding strength is ensured.

### Solution to Problem

In order to achieve the above object, the present invention has the following constitutions.

According to a first aspect of the present invention, there is provided a semiconductor device mounting method for performing ultrasonic bonding of a second electrode of a semiconductor device to a first electrode of a board placed on a board stage, the method comprising:

a bonding-auxiliary-agent feeding step for feeding a bonding auxiliary agent onto the first electrode or the second electrode, whichever at least one electrode is formed from copper; and

a ultrasonic bonding step for metal-joining the first electrode and the second electrode by applying ultrasonic vibrations to the electrodes with the second electrode being pressed against the first electrode, wherein

in the ultrasonic bonding step, the bonding auxiliary agent keeps present at least in a periphery of a bonding interface between the first electrode and the second electrode at least until the first electrode and the second electrode are metal-joined.

According to a second aspect of the present invention, there is provided the semiconductor device mounting method according to the first aspect, wherein

the bonding auxiliary agent has reducibility, and

in the ultrasonic bonding step, the bonding interface between the first electrode and the second electrode is locally heated when the first electrode and the second electrode are metal-joined, so that the bonding auxiliary agent generates reductive reaction by utilizing the heat.

According to a third aspect of the present invention, there is provided the semiconductor device mounting method according to the second aspect, wherein

the first electrode of the board is formed from copper, and

in the bonding-auxiliary-agent feeding step, the bonding auxiliary agent is fed onto the first electrode of the board.

According to a fourth aspect of the present invention, there is provided the semiconductor device mounting method according the second aspect, wherein

the first electrode of the board is formed from copper while the second electrode of the semiconductor device is formed from gold, and

in the ultrasonic bonding step, the first electrode and the second electrode are metal-joined in a state that the bonding auxiliary agent is present in the periphery of the bonding interface between the first electrode formed from copper and the second electrode formed from gold.

According to a fifth aspect of the present invention, there is provided the semiconductor device mounting method according to the second aspect, further comprising a bonding-auxiliary-agent removal step for removing the bonding auxiliary agent remaining between the board and the semiconductor device after the ultrasonic bonding step.

According to a sixth aspect of the present invention, there is provided the semiconductor device mounting method according to the fifth aspect, wherein in the bonding-auxiliary-agent removal step, the bonding auxiliary agent is removed by heating and vaporizing the bonding auxiliary agent remaining between the board and the semiconductor device.

According to a seventh aspect of the present invention, there is provided the semiconductor device mounting method according to the second aspect, further comprising an oxide removal step for removing oxide on at least either one of the first electrode or the second electrode whichever is formed from copper, before the bonding-auxiliary-agent feeding step.

According to a eighth aspect of the present invention, there is provided the semiconductor device mounting method according to the second aspect, wherein the bonding auxiliary agent has an OH group.

According to a ninth aspect of the present invention, there is provided the semiconductor device mounting method according to the second aspect, wherein the bonding auxiliary agent has a boiling point of 200° C. or higher.

According to a tenth aspect of the present invention, there is provided a method for manufacturing a semiconductor device mounted board, the method including:

the semiconductor device mounting method according to any one of the second aspect to the ninth aspect, and

a resin sealing step for sealing, with resin, areas including gaps between the board and the semiconductor device as well as bonding portions between the first electrodes and the second electrodes after the bonding-auxiliary-agent removal step.

According to a eleventh aspect of the present invention, there is provided a method for manufacturing a light-emitting device mounted board, the method including:

the semiconductor device mounting method according to the first aspect, wherein the semiconductor device of the second electrode is a light-emitting device;

a bonding-auxiliary-agent removal step for removing the bonding auxiliary agent remaining between the board and the light-emitting device; and

a resin sealing step for sealing, with light-transmitting resin, areas including gaps between the board and the light-emitting device as well as bonding portions between the first electrodes and the second electrodes, wherein

in the ultrasonic bonding step, the bonding interface between the first electrode and the second electrode keeps covered with the bonding auxiliary agent at least until the first electrode and the second electrode are metal-joined.

According to a twelfth aspect of the present invention, there is provided the method for manufacturing a light-emitting device mounted board according to the eleventh aspect, further comprising an oxide removal step for removing oxide on at least either one of the first electrode or the second electrode whichever is formed from copper, before the bonding-auxiliary-agent feeding step.

According to a thirteenth aspect of the present invention, there is provided the method for manufacturing a light-emitting device mounted board according to the twelfth aspect, wherein

the first electrode of the board is formed from copper,

in the oxide removal step, oxide on the first electrode of the board is removed, and

in the bonding-auxiliary-agent feeding step, the bonding auxiliary agent is fed onto the first electrode of the board.

According to a fourteenth aspect of the present invention, there is provided the method for manufacturing a light-emitting device mounted board according to the twelfth aspect, wherein

the first electrode of the board is formed from copper while the second electrode of the light-emitting device is formed from gold, and

in the ultrasonic bonding step, the first electrode and the second electrode are metal joined in a state that a contact interface between the first electrode formed from copper and the second electrode formed from gold is covered with the bonding auxiliary agent.

According to a fifteenth aspect of the present invention, there is provided the method for manufacturing a light-emitting device mounted board according to the twelfth aspect, wherein in the bonding-auxiliary-agent removal step, the bonding auxiliary agent is removed by heating and vaporizing the bonding auxiliary agent remaining between the board and the light-emitting device.

According to a sixteenth aspect of the present invention, there is provided the method for manufacturing a light-emitting device mounted board according to the twelfth aspect, wherein the bonding auxiliary agent has an OH group.

According to a seventeenth aspect of the present invention, there is provided the method for manufacturing a light-emitting device mounted board according to any one of the twelfth aspect to the sixteenth aspect, wherein the bonding auxiliary agent has a boiling point of 200° C. or higher.

### Effects of Invention

The inventors performed analysis of bonding interfaces between Cu electrodes of a board and Au bumps of a light-emitting device, which were ultrasonically bonded together in the atmospheric air. As a result, the inventors confirmed that the surfaces of the Cu electrodes discolored black, and moreover analyzed the black-discolored portions in detail, proving that those portions were oxide of copper. From this fact, the inventors obtained a conclusion that new oxide was generated on the surfaces of the Cu electrodes due to frictional heat caused by the ultrasonic bonding, and the oxide inhibited the bonding (junction) to the Cu electrodes, thus reaching the completion of this invention.

According to the present invention, when metal junction between a first electrode and a second electrode is executed as ultrasonic bonding between metals including at least copper, the ultrasonic bonding is performed in a state that the bonding auxiliary agent is present in a periphery of a bonding interface between the first electrode and the second electrode. As a result, formation of oxide at the bonding interface (contact interface) between the first electrode and the second electrode due to execution of the ultrasonic bonding can be suppressed. Therefore, while a desired bonding strength is ensured, ultrasonic bonding with copper used for the first electrode or the second electrode can be fulfilled and cost cuts in semiconductor device mounting can be achieved.

### BRIEF DESCRIPTION OF DRAWINGS

These aspects and features of the present invention will become clear from the following description taken in conjunction with the preferred embodiments thereof with reference to the accompanying drawings, in which:

FIG. 1 is a sectional view of a board in a state that a plurality of light emitting devices are mounted by a semiconductor device mounting method according to an embodiment of the present invention;

FIG. 2 is a structural view of a bonding unit for carrying out the mounting method of the embodiment of the invention;

FIG. 3 is a flowchart showing a procedure of the mounting method of the embodiment of the invention;

FIG. 4 is an explanatory view of individual steps in the mounting method of the embodiment of the invention; and

FIG. 5 is a chart resulting from measuring die shearing strength with respect to a board manufactured by the mounting method of the embodiment of the invention.

### DESCRIPTION OF EMBODIMENTS

Before the description of the present invention proceeds, it is to be noted that like parts are designated by like reference numerals throughout the accompanying drawings. Hereinbelow, embodiments of the present invention will be described with reference to the accompanying drawings.

### Embodiment 1

FIG. 1 shows a plurality of semiconductor devices mounted by using a semiconductor device mounting method according to an embodiment of the present invention.

As shown in FIG. 1, a plurality of interconnecting lines 2 are formed on a top surface of a circuit board 1 as in the figure, and an end portion of each interconnecting line 2 is formed as a board electrode (first electrode) 3. Light-emitting devices (LED chip) 4, which are an example of the semiconductor device, have bumps (second electrodes) 5 connected to their respective board electrodes 3. In this case, the interconnecting lines 2 of the board 1 are formed from copper as an example, and the board electrodes 3 are formed also from copper. The bump 5 of the light-emitting device 4 is formed from gold or copper as an example. The description of this embodiment is made on a case where the interconnecting lines 2 and the board electrodes 3 are formed from copper (Cu) while the bumps 5 are formed from gold (Au), as an example.

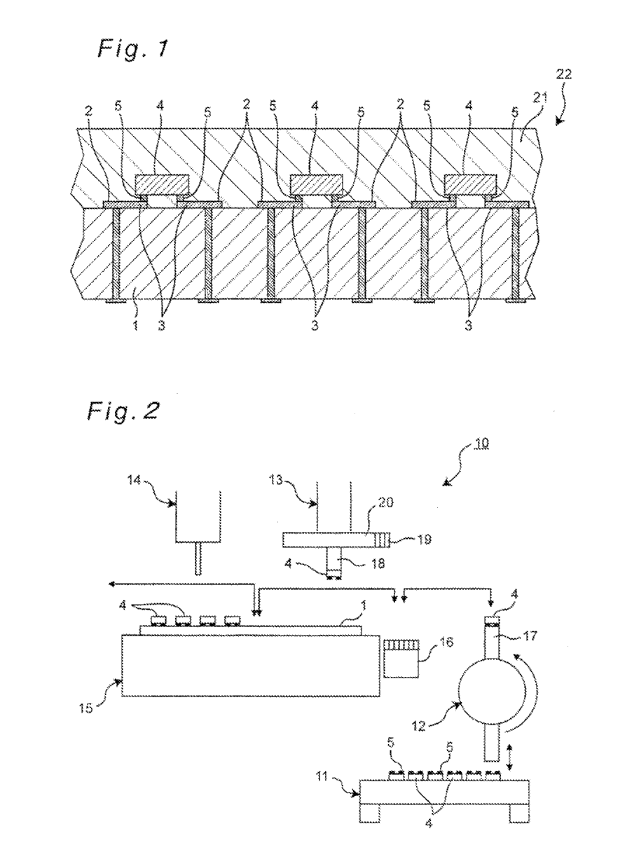

Next, a main structure of a flip chip bonding unit to be used for the semiconductor device mounting method by ultrasonic bonding (or joining) according to this embodiment is described with reference to FIG. 2.

As shown in FIG. 2, a bonding unit 10 includes a device feeding block 11 for feeding a plurality of light-emitting devices 4, a device inversion unit 12 for sucking-and-holding a light-emitting device 4 fed from the device feeding block 11 and moreover vertically inverting the held light-emitting device 4, a bonding head 13 for receiving, and sucking and holding, the light-emitting device 4 inverted by the device inversion unit 12 and then mounting the light-emitting device 4 to a specified position on the board 1, a dispenser unit 14 for applying a later-described bonding auxiliary agent on each board electrode 3 of the board 1, a board stage 15 for placing thereon and holding the board 1, and a camera unit 16 for capturing an image of the light-emitting device 4 held by the bonding head 13 to recognize a holding posture of the light-emitting device 4.

On a top surface of the device feeding block 11, a plurality of light-emitting devices 4 are arrayed with their bump 5 formation surfaces being upward. The device feeding block 11 is movable in an X direction and a Y direction extending in a direction along the surface of the board 1 (horizontal direction) and orthogonally crossing with each other. Movement of the device feeding block 11 in the X-Y directions allows one light-emitting device 4 and the device inversion unit 12 to be positionally aligned with each other.

The device inversion unit 12, having a nozzle 17 for releasably sucking and holding the light-emitting device 4, inverts the nozzle 17 with the light-emitting device 4 sucked and held thereto vertically to 180 degrees, so that the posture of the light-emitting device 4 is inverted in the vertical direction.

The bonding head 13 includes a nozzle 18 for releasably sucking and holding the light-emitting device 4, a vibrator 19 for generating ultrasonic vibrations, and an ultrasonic horn 20 for amplifying ultrasonic vibrations generated by the vibrator 19 and transferring the amplified vibrations to the nozzle 18. Also, the bonding head 13 is movable in the X-Y directions, and X-Y movement and positioning of the bonding head 13 to a specified position leads to fulfillment of such operations as a delivery operation of the light-emitting device 4 from the device inversion unit 12 to the bonding head 13 and an image capture operation of a held posture of the light-emitting devices 4 by the camera unit 16.

The dispenser unit 14 is movable in the X-Y directions and serves for coating and supplying of a specified quantity of bonding auxiliary agent onto each board electrode 3 formed on the board 1.

The board stage 15, containing a heater (not shown), has a function of heating the set-on board 1 to a specified temperature.

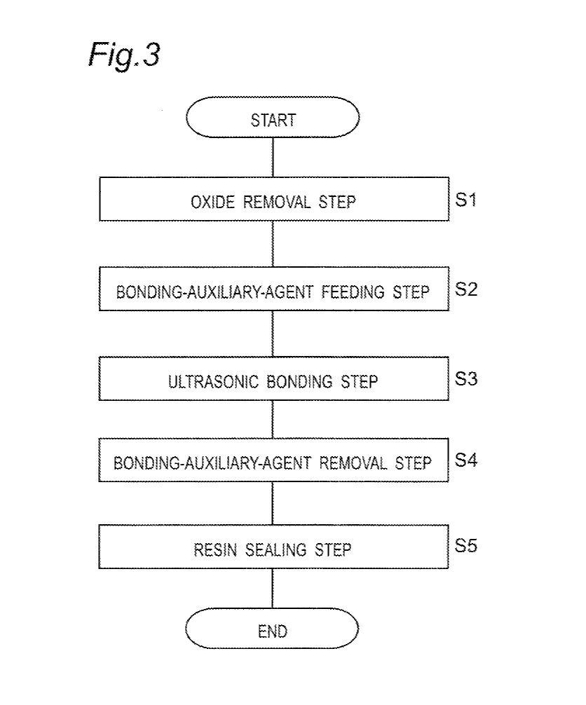

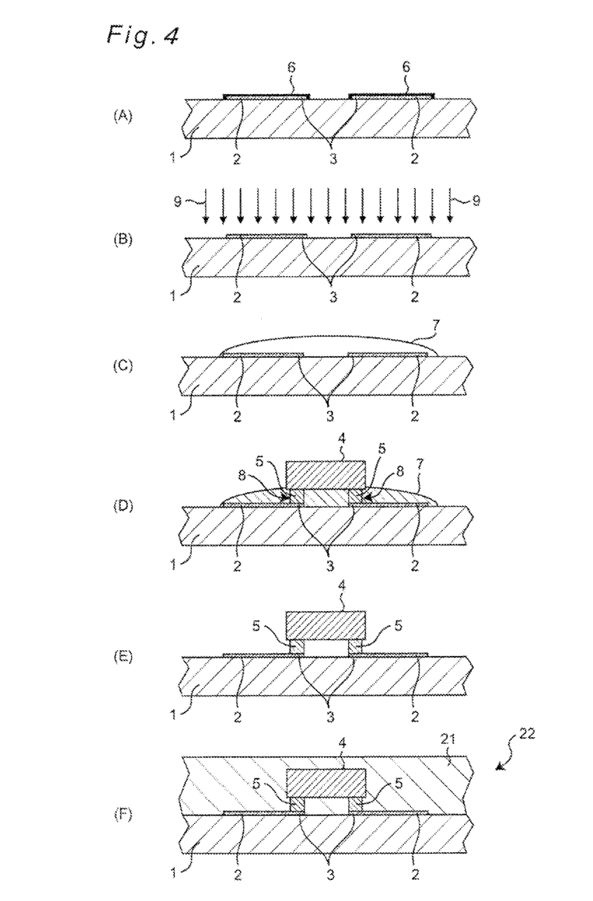

Next, the procedure for manufacturing a semiconductor device mounted board by mounting a plurality of light-emitting devices 4 onto the board 1 by ultrasonic bonding with use of such a bonding unit 10 as described above is described concretely below. In relation to this description, FIG. 3 shows a flowchart of the procedure, and FIGS. 4(A)-(F) show explanatory views of individual steps shown in the flowchart, respectively.

(Oxide Removal Step)

The interconnecting lines 2 and the board electrodes 3 of the board 1 are formed from copper. Therefore, as shown in FIG. 4(A), oxide 6 is formed on the surface of each interconnecting line 2 and board electrode 3, which is a copper surface. First, the oxide 6 is removed (step S1).

More specifically, with use of an atmospheric plasma generation device (not shown), a plasma is generated by feeding a hydrogenated Ar gas and moreover applying radio-frequency energy to the hydrogenated Ar gas. As shown in FIG. 4(B), feeding the generated plasma 9 to the surfaces of the interconnecting line 2 and board electrode 3 of the board 1 causes the reduction process of the oxide 6 by the plasma 9, so that the oxide 6 is removed. Exposing only removal portions of the oxide 6 to the plasma 9 makes it possible to effectively remove the oxide 6. As the atmospheric plasma generation device, those described in JP 2009-206022 A or JP 2009-259626 A are applicable. It is noted that such an oxide removal step can be carried out by not only a process using atmospheric plasma but also a process using batch plasma, and moreover removal and reduction methods without plasma are also usable.

In addition, since the oxide removal step is aimed at removing oxide of copper already formed at bonding-purpose portions before bonding, the oxide removal step may be omitted depending on circumstances with considerations given to the removal amounts by later-described reduction process of the bonding auxiliary agent and with discussions about the necessity of execution of the oxide removal step according to the quantity of formed oxide of copper.

(Bonding-Auxiliary-Agent Feeding Step)

Upon an end of the oxide removal step, the board 1 is set and held on the board stage 15 of the bonding unit 10. Thereafter, by the dispenser unit 14, the bonding auxiliary agent is fed to the surfaces of the interconnecting line 2 and the board electrode 3 with the oxide 6 removed therefrom (step S2).

It is noted here that the bonding auxiliary agent refers to a liquid- or paste-state agent which has reducibility and which covers the bonding interface (contact interface) between the board electrode 3 and the bump 5 in a later-described ultrasonic bonding step to remove the oxide formed on the bonding interface and suppress oxidation in the bonding interface. The bonding auxiliary agent is also an agent which, after fulfillment of the ultrasonic bonding, vaporizes and is thereby removed from the bonding interface and its vicinities by execution of a later-described bonding-auxiliary-agent removal step. Preferably, as the bonding auxiliary agent, a solvent containing an OH group is used so that the function of reducibility of copper to the surface can be ensured in the bonding interface. As an example of the bonding auxiliary agent having such a feature, glycerin is used in this embodiment. In addition, bonding auxiliary agents containing silica filler, metal particles or non-evaporable resin components would make it difficult to remove the bonding auxiliary agent in the bonding-auxiliary-agent removal step, thus the bonding auxiliary agent preferably containing no such substances.

In the bonding unit 10, alignment between a desired board electrode 3 (or interconnecting line 2) on the board 1 and the dispenser unit 14 is performed by moving the dispenser unit 14 in the X-Y directions, and a bonding auxiliary agent 7 (e.g., glycerin) is applied and fed onto the board electrode 3 by the dispenser unit 14. As a result, in a mounting position of the light-emitting device 4 to the board 1, as shown in FIG. 4(C), the bonding auxiliary agent 7 is placed so as to cover the entirety of the individual board electrodes 3 and their vicinal interconnecting lines 2.

(Ultrasonic Bonding Step)

Next, in the bonding unit 10, one light-emitting device 4 is sucked and held by the nozzle 17 of the device inversion unit 12 so as to be picked up from the device feeding block 11, and the nozzle 17 is vertically inverted by the device inversion unit 12, by which the held light-emitting device 4 is inverted. Thereafter, the bonding head 13 is positioned to above the device inversion unit 12 in the inverted state, in which state the light-emitting device 4 is delivered from the device inversion unit 12 to the nozzle 18 of the bonding head 13. The bonding head 13 is moved in the X-Y directions so as to be positioned to above the mounting position on the board 1, to which the bonding auxiliary agent 7 has previously been fed. Subsequently, the bonding head 13 is moved down, so that the individual bumps 5 of the light-emitting device 4 held by the nozzle 18 are pressed into contact with the individual board electrodes 3 of the board 1. Meanwhile, since the bonding auxiliary agent 7 has been fed on the individual board electrodes 3 and their vicinal interconnecting lines 2, bonding interfaces 8 between the bumps 5 of the light-emitting device 4 and the board electrodes 3 are covered with the bonding auxiliary agent 7 (see FIG. 4(D)).

In this state, ultrasonic vibrations are generated in the bonding head 13 by the vibrator 19, and the generated ultrasonic vibrations are amplified by the ultrasonic horn 20, thus being applied to the light-emitting device 4 through the nozzle 18. By those ultrasonic vibrations applied to the bonding interfaces 8 between the bumps 5 of the light-emitting device 4 and the board electrodes 3, the bumps 5 and the board electrodes 3 are metal bonded (i.e., ultrasonically bonded) to each other (step S3). After that, the generation of ultrasonic vibrations by the vibrator 19 is stopped and the sucking and holding of the light-emitting device 4 by the nozzle 18 is released so that the nozzle 18 is moved up so as to go off from the light-emitting device 4.

As described above, in the ultrasonic bonding step, since the board electrodes 3 are pressed with the bumps 5 of the light-emitting device 4, a load is applied to the board electrodes 3 via the bumps 5. In the state that the load applied is from the bumps 5 of the light-emitting device 4 to the board electrodes 3 as shown above, ultrasonic vibrations, when applied to the bonding interfaces 8, cause the bonding interfaces 8 to become locally high in temperature due to frictional heat. With conventional ultrasonic bonding using no bonding auxiliary agent, it has been considered that this high temperature due to frictional heat would accelerate alloy junction (bonding). Actually, however, oxidation (black film) of the surface of the copper (board electrodes 3) progresses, so that not enough bonding strength can be ensured.

In contrast to this, in this invention, ultrasonic bonding is performed under the condition that the bonding auxiliary agent 7 having reducibility is present in vicinities of the bonding interface 8. Therefore, the bonding auxiliary agent placed so as to cover the bonding interface 8 generates reductive reaction by utilizing the frictional heat. As a consequence, whereas heat generated by ultrasonic bonding on copper may act on copper to newly form oxide of copper, the oxidation of copper during ultrasonic bonding can be suppressed by the above-described reductive reaction effected by the bonding auxiliary agent.

Also, in such a case where the above-described oxide removal step is omitted or where the removal of oxide in the oxide removal step is insufficient, it can be assumed that the oxide may remain on the copper surface. However, by the reductive reaction generated by the bonding auxiliary agent as described above, the oxide of copper that has already been formed on the bonding interface 8 can be reduced and removed off.

Further, during execution of the ultrasonic bonding, i.e., until completion of the ultrasonic bonding, at least the bonding interfaces 8 between the bumps 5 and the board electrodes 3 is covered by the bonding auxiliary agent 7, thus being kept from contact with oxygen. Therefore, formation of oxide at the bonding interface 8 or its vicinities by ultrasonic bonding can be suppressed.

As described above, since the ultrasonic bonding is carried out under prevention of oxidation of the copper surface by the bonding auxiliary agent, the alloy junction between oxide-free copper and the bumps 5 can be achieved securely.

In this ultrasonic bonding step, a series of operations from the pick-up operation of the light-emitting device 4 from the device feeding block 11 to the delivery operation of the light-emitting device 4 to the bonding head 13 may also be executed in parallel with the bonding-auxiliary-agent feeding step.

(Bonding-Auxiliary-Agent Removal Step)

Next, removal of the bonding auxiliary agent 7 remaining between the board 1 and the light-emitting device 4 is executed (step S4). More specifically, the board 1 is heated to accelerate vaporization of the bonding auxiliary agent 7, thereby achieving the removal of the bonding auxiliary agent 7. The method of heating the board 1 in such a case may be, for example, to heat the board 1 by using the board stage 15 of the bonding unit 10 or to heat the board 1 by using some other heating means, and moreover a drying acceleration means such as spraying hot air may also be used. As a result of this, as shown in FIG. 4(E), the bonding auxiliary agent 7 that has been remaining between the board 1 and the light-emitting device 4 is removed, thus the mounting of the light-emitting device 4 onto the board 1 being completed.

In addition, the bonding-auxiliary-agent removal step is aimed at removing the bonding auxiliary agent remaining after the ultrasonic bonding step prior to a later-described resin sealing step, it is also possible to omit the bonding-auxiliary-agent removal step as the case may be based on discussions as to the necessity for execution of the bonding-auxiliary-agent removal step depending on the quantity of the remaining bonding auxiliary agent.

(Resin Sealing Step)

Next, bonding (junction) portions between the board 1 and the light-emitting device 4 or the like are sealed by resin to thereby complete the light-emitting device mounted board (step S5). More specifically, resin 21 is applied so as to cover the surfaces of the interconnecting lines 2, the board electrodes 3 and the bumps 5 including the bonding interfaces 8 between the board electrodes 3 and the bumps 5, so that the light-emitting device 4 and the board 1 are sealed from each other. The resin 21 may be given by using a resin having light permeability to fulfill the light-emitting property. As a result, as shown in FIG. 4(F), the board 1 and the light-emitting device 4 are sealed from each other by the resin 21, thus the manufacture of a light-emitting device mounted board 22 being completed.

In addition, in a case where a plurality of light-emitting devices 4 are mounted onto the board 1, the procedure steps from the above-described oxide removal step to the resin sealing step are executed in succession, so that the individual light-emitting devices 4 are mounted onto the board 1 and the light-emitting device mounted board 22 is manufactured. Furthermore, the oxide removal step (step S1), the bonding-auxiliary-agent feeding step (step S2), and the bonding-auxiliary-agent removal step (step S4) may also be executed collectively for a plurality of mounting positions on the board 1, instead of cases where those steps are executed for each one single mounting position on the board 1.

According to this embodiment, while a load is applied from the bumps 5 (Au) to the board electrodes 3 (Cu), ultrasonic vibrations are applied to locally heat the bonding interfaces 8 between the bumps 5 and the board electrodes 3, so that the bonding auxiliary agent 7 placed so as to cover the bonding interface 8 generates reductive reaction by utilizing the resultant frictional heat. With utilization of the reductive reaction, heat of the ultrasonic bonding acts on copper so that formation of new oxide of copper can be suppressed and moreover the oxide of copper already formed on the bonding interface 8 can be removed. Further, by coverage over the bonding interface 8, the surfaces of Cu, which is easier to oxidize than Au, can be inhibited from contact with oxygen, so that the bonding interface 8 can be prevented from formation of oxide on the bonding interface 8 due to ultrasonic bonding. Thus, since the ultrasonic bonding is executed while oxidation of the copper surfaces is prevented by the bonding auxiliary agent, the alloy junction of oxide-free copper and the bumps 5 can be achieved securely. That is, die shearing strength preferred for Au—Cu junction can be maintained, so that metal junction (metal-joining) substitutable for conventional Au—Au junction can be provided and moreover cost cuts in the mounting of semiconductor devices as well as the manufacture of semiconductor device mounted boards can be fulfilled. Besides, utilization of local high temperatures by ultrasonic bonding eliminates the need for increasing the temperature of the overall board or chip, also eliminating the need for any large-scale reduction-use heating device or the like, so that further cost cuts can be fulfilled.

Since the bonding auxiliary agent 7 shown above is removed from on the board 1 by execution of the bonding-auxiliary-agent removal step after completion of ultrasonic bonding, impairment of the functions of the light-emitting devices 4 and the board 1 never occurs.

Also, the surfaces of the interconnecting lines 2 and the board electrodes 3 of the board 1 are subjected to the oxide removal step and then the ultrasonic bonding step is executed with the individual surfaces covered by the bonding auxiliary agent. Therefore, oxide is not formed once again on the surfaces of the interconnecting lines 2 and the board electrodes 3. As a result, the surfaces of the interconnecting lines 2 and the board electrodes 3 formed from copper (Cu) are maintained as high-brightness surfaces equivalent to the surfaces of Au. Thus, light from the light-emitting device 4 can be reflected efficiently. Accordingly, while Cu, lower in price than Au, is used as the material of the interconnecting lines and board electrodes of the board, light derived from the semiconductor device can efficiently be reflected so that luminous efficacy can be enhanced. Furthermore, in the resin sealing step, for the sealing of the board 1 and the like by using light-transmitting resin, the high-brightness state of the surfaces of the interconnecting lines 2 and the board electrodes 3 can be maintained.

Next, the bonding auxiliary agent to be used for the invention is further described. The bonding auxiliary agent serves a role of, until completion of the ultrasonic bonding, covering the bonding interfaces between the bumps and the board electrodes to intercept oxygen as well as another role of generating reductive reaction to reduce the oxide of copper. Meanwhile, in the bonding unit 10, the board 1 held by the board stage 15 is, normally, as is often the case, previously heated (increased in temperature) to a specified temperature so that ultrasonic bonding of the light-emitting device 4 to the board 1 can be achieved effectively. The bonding auxiliary agent 7 fed onto the interconnecting lines 2 and the board electrodes 3 of the board 1 heated as described above needs to keep remaining and covering the bonding interface, without vaporizing in quite short time, at least until completion of the ultrasonic bonding. For example, solvents having a boiling point 50° C. or more higher than the temperature of the board stage 15, on which the board 1 is to be placed, can be prevented from vaporizing and dissipating in quite shorter time after being fed. That is, under the condition that an upper limit of the temperature of the board stage 15 is set to 150° C., the boiling point of the solvent is preferably not less than 200° C.

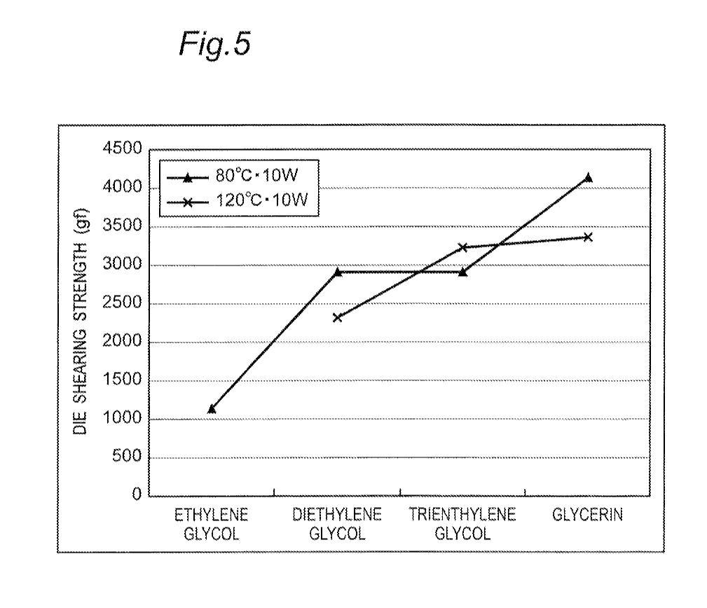

With respect to mounted semiconductor devices by using various types of bonding auxiliary agents, measurement experiments of die shearing strength were performed, and their experiment results are shown in FIG. 5. In FIG. 5, the horizontal axis represents the types of bonding auxiliary agent, and vertical axis represents die shearing strengths (gf) of light-emitting devices using those bonding auxiliary agents. In this case, a result with ethylene glycol (boiling point: 198° C.) used as the bonding auxiliary agent is shown as a comparative example, and results with diethylene glycol (boiling point: 244-245° C.), trienthylene glycol (boiling point: 288° C.) and glycerin (boiling point: 290° C.) used as the bonding auxiliary agent are shown as examples. As to experimental conditions, the size of a semiconductor device mounted board was 4 mm×4 mm, the size of a bump was 90 μm×30 μm, and the quantity of bumps was 288 pcs, and the bumps are Au-plated bumps in terms of material. Further, in addition to those conditions, experiments were performed each under two-pattern conditions (patterns 1, 2), i.e., a temperature of the board stage 15 of 80° C., a load of 30 N and an ultrasonic power of 10 W, and a temperature of the board stage 15 of 120° C., a load of 30 N and an ultrasonic power of 10 W.

As to the die shearing strength of the semiconductor device mounted boards, a decision criterion was set to 2000 gf. As shown in FIG. 5, the die shearing strength of the semiconductor device in Comparative Example was 2000 gf or less in either case of patterns 1 and 2. On the other hand, the die shearing strengths of the semiconductor device mounted boards in Examples were 2000 gf or more in either case of patterns 1 and 2. From these settings and results, it can be understood that for the bonding auxiliary agent of the invention, ethylene glycol used in Comparative Example is unsuitable while diethylene glycol, trienthylene glycol and glycerin used in Example are suitable.

The bonding auxiliary agent needs to be securely removed from on the board by using a simple method after fulfilling the roles of covering the bonding interface to intercept oxygen and moreover generating reductive reaction. For this purpose, the bonding auxiliary agent needs to be in such a type as the agent, when heated, vaporizes so as to be removed without remaining on the board.

Also, the bonding auxiliary agent, by virtue of its having at least one OH group, can ensure the reducibility effect to the bonding interface and the like.

As a result of generalizing the conditions required for the bonding auxiliary agent as shown above, the bonding auxiliary agent of the invention may be provided by using, for example, glycerin, trienthylene glycol, and diethylene glycol used in the above Example, and moreover diethylene glycol mono/n butyl ether (boiling point: 230° C.), trienthylene glycol dimethyl ether (boiling point: 216° C.), tetraethylene glycol (boiling point: 327° C.), and the like.

As the feeding position for the bonding auxiliary agent, the above description has been made on a case where the bonding auxiliary agent covers peripheries of the bonding interface 8. Alternatively, the bonding auxiliary agent may also be fed so as to be present at least in vicinities of the contact interface. In this case, in the ultrasonic bonding step, since the bonding auxiliary agent present in vicinities of the bonding interface 8 is let to penetrate into the bonding interface 8 by action of the ultrasonic vibrations, it becomes implementable to remove already formed oxide of copper as well as suppress the formation of new oxide of copper similarly by the above-described reductive reaction and the like.

### Embodiment 2

Next, Embodiment 2 will be described only in terms of its differences from Embodiment 1.

In Embodiment 1, a solvent that has reducibility and intercepts oxygen is used as the bonding auxiliary agent. In contrast, in this Embodiment 2, a solvent for merely intercepting oxygen independent of its having reducibility or not is used. That is, the bonding auxiliary agent to be used in this Embodiment 2 is a liquid- or paste-state solvent that covers the bonding interface (contact interface) between the board electrodes 3 and the bumps 5 to suppress oxidation of the bonding interface during the ultrasonic bonding step. It is noted that Embodiment 1 and this Embodiment 2 differ from each other only in the property of the bonding auxiliary agent and are common to each other in terms of the mounting procedure and steps.

According to this Embodiment 2, ultrasonic bonding between the bumps 5 and the board electrodes 3 is executed while the bonding interfaces 8 between the bumps 5 (Au) of the light-emitting device 4 and the board electrodes 3 (Cu) of the board 1 is covered with the bonding auxiliary agent 7. Therefore, the surfaces of Cu, which is easier to oxidize than Au, can be inhibited from making contact with oxygen, so that formation of oxide on the bonding interface 8 due to ultrasonic bonding can be prevented. Therefore, die shearing strength preferred for Au—Cu junction can be maintained, so that metal junction substitutable for conventional Au—Au junction can be provided and moreover cost cuts in the mounting of light-emitting devices as well as the manufacture of light-emitting device mounted boards can be fulfilled.

Preferably, in this Embodiment 2, for the purpose of preventing progress of oxidation of copper due to high temperatures over 150° C., the temperature of the board stage 15 is previously controlled to 50° C.-150° C., and this temperature is kept from the oxide removal step until the succeeding bonding-auxiliary-agent feeding step and ultrasonic bonding step.

Using, as the bonding auxiliary agent, a solvent having an oxygen intercepting function independent of its having reducibility or not as described above makes it possible to use a wide variety of types of bonding auxiliary agents without being limited to glycerin or the like.

The above description of the embodiments has been made on a case where the bumps 5 (Au) of the light-emitting device 4 and the board electrodes 3 (Cu) of the board 1 are ultrasonically bonded together as an example. Alternatively, the case may be such that the bumps 5 of the light-emitting device 4 may also be formed from copper and Cu—Cu ultrasonic bonding is executed. Furthermore, it is also allowable that the bumps 5 are formed from copper while the board electrodes 3 are formed from gold, and Cu—Au ultrasonic bonding is executed.

Also, the above description has been given on a case, as an example, where the bonding auxiliary agent is applied and fed onto the interconnecting line 2 and the board electrode 3 of the board 1 by using the dispenser unit 14. However, as the method for feeding the bonding auxiliary agent, a feeding method by transfer may also be adopted. Further, the case may also be that the bonding auxiliary agent is fed to the board 1 side, or fed to the light-emitting device 4 side, or fed to both, whichever method is adoptable.

In the oxide removal step, portions exposed to the atmospheric plasma out of the surfaces of the interconnecting line 2 and the board electrode 3 or the like become areas where the bonding auxiliary agent is more likely to be wetted and stretched upon feed of the bonding auxiliary agent afterwards. Therefore, controlling the areas exposed to the atmospheric plasma makes it possible to control the feeding area of the bonding auxiliary agent and moreover to properly control the feed amount of the bonding auxiliary agent.

Also, in the bonding-auxiliary-agent removal step, instead of the case where the bonding auxiliary agent is removed by aggressive heating or the like, the case may be that the bonding auxiliary agent is removed by leaving the agent as it is to let the agent naturally vaporize, as an example.

It is to be noted that, by properly combining the arbitrary embodiments of the aforementioned various embodiments, the effects possessed by them can be produced.

The present invention is capable of fulfilling Au—Cu junction or Cu—Cu junction in semiconductor device mounting while a die shearing strength equivalent to that of conventional Au—Au junction is maintained, thus being useful for semiconductor device mounting methods under high continuous demands for cost cuts.

Although the present invention has been fully described in connection with the preferred embodiments thereof with reference to the accompanying drawings, it is to be noted that various changes and modifications are apparent to those skilled in the art. Such changes and modifications are to be understood as included within the scope of the present invention as defined by the appended claims unless they depart therefrom.

The entire disclosure of Japanese Patent Applications No. 2011-070310 filed on Mar. 28, 2011 and No. 2011-070318 filed on Mar. 28, 2011 including specification, claims, and drawings are incorporated herein by reference in its entirety.

1. A semiconductor device mounting method for performing ultrasonic bonding of a second electrode of a semiconductor device to a first electrode of a board placed on a board stage, the method comprising:
a bonding-auxiliary-agent feeding step for feeding a bonding auxiliary agent onto the first electrode or the second electrode, whichever at least one electrode is formed from copper; and
a ultrasonic bonding step for metal joining the first electrode and the second electrode by applying ultrasonic vibrations to the electrodes with the second electrode being pressed against the first electrode, wherein
in the ultrasonic bonding step, the bonding auxiliary agent keeps present at least in a periphery of a bonding interface between the first electrode and the second electrode at least until the first electrode and the second electrode are metal-joined.

2. The semiconductor device mounting method according to claim 1, wherein
the bonding auxiliary agent has reducibility, and
in the ultrasonic bonding step, the bonding interfaces between the first electrode and the second electrode is locally heated when the first electrode and the second electrode are metal-joined, so that the bonding auxiliary agent generates reductive reaction by utilizing the heat.

3. The semiconductor device mounting method according to claim 2, wherein
the first electrode of the board is formed from copper, and
in the bonding-auxiliary-agent feeding step, the bonding auxiliary agent is fed onto the first electrode of the board.

4. The semiconductor device mounting method according to claim 2, wherein
the first electrode of the board is formed from copper while the second electrode of the semiconductor device is formed from gold, and
in the ultrasonic bonding step, the first electrode and the second electrode are metal-joined in a state that the bonding auxiliary agent is present in the periphery of the bonding interface between the first electrode formed from copper and the second electrode formed from gold.

5. The semiconductor device mounting method according to claim 2, further comprising a bonding-auxiliary-agent removal step for removing the bonding auxiliary agent remaining between the board and the semiconductor device after the ultrasonic bonding step.

6. The semiconductor device mounting method according to claim 5, wherein in the bonding-auxiliary-agent removal step, the bonding auxiliary agent is removed by heating and vaporizing the bonding auxiliary agent remaining between the board and the semiconductor device.

7. The semiconductor device mounting method according to claim 2, further comprising an oxide removal step for removing oxide on at least either one of the first electrode or the second electrode whichever is formed from copper, before the bonding-auxiliary-agent feeding step.

8. The semiconductor device mounting method according to claim 2, wherein the bonding auxiliary agent has an OH group.

9. The semiconductor device mounting method according to claim 2, wherein the bonding auxiliary agent has a boiling point of 200° C. or higher.

10. A method for manufacturing a semiconductor device mounted board, the method including:
the semiconductor device mounting method according to claim 2, and
a resin sealing step for sealing, with resin, areas including gaps between the board and the semiconductor device as well as bonding portions between the first electrodes and the second electrodes after the bonding-auxiliary-agent removal step.

11. A method for manufacturing a light-emitting device mounted board, the method including:
the semiconductor device mounting method according to the first aspect, wherein the semiconductor device of the second electrode is a light-emitting device;
a bonding-auxiliary-agent removal step for removing the bonding auxiliary agent remaining between the board and the light-emitting device; and
a resin sealing step for sealing, with light-transmitting resin, areas including gaps between the board and the light-emitting device as well as bonding portions between the first electrodes and the second electrodes, wherein
in the ultrasonic bonding step, the bonding interface between the first electrode and the second electrode keeps covered with the bonding auxiliary agent at least until the first electrode and the second electrode are metal-joined.

12. The method for manufacturing a light-emitting device mounted board according to claim 11, further comprising an oxide removal step for removing oxide on at least either one of the first electrode or the second electrode whichever is formed from copper, before the bonding-auxiliary-agent feeding step.

13. The method for manufacturing a light-emitting device mounted board according to claim 12, wherein
the first electrode of the board is formed from copper,
in the oxide removal step, oxide on the first electrode of the board is removed, and
in the bonding-auxiliary-agent feeding step, the bonding auxiliary agent is fed onto the first electrode of the board.

14. The method for manufacturing a light-emitting device mounted board according to claim 12, wherein
the first electrode of the board is formed from copper while the second electrode of the light-emitting device is formed from gold, and
in the ultrasonic bonding step, the first electrode and the second electrode are metal-joined in a state that a contact interface between the first electrode formed from copper and the second electrode formed from gold is covered with the bonding auxiliary agent.

15. The method for manufacturing a light-emitting device mounted board according to claim 12, wherein in the bonding-auxiliary-agent removal step, the bonding auxiliary agent is removed by heating and vaporizing the bonding auxiliary agent remaining between the board and the light-emitting device.

16. The method for manufacturing a light-emitting device mounted board according to claim 12, wherein the bonding auxiliary agent has an OH group.

17. The method for manufacturing a light-emitting device mounted board according to claim 12, wherein the bonding auxiliary agent has a boiling point of 200° C. or higher.
